(19) United States
(12) Patent Application Publication
(10) Pub. No.: US 2025/0219630 A1
(43) Pub. Date: Jul. 3, 2025

(54) CIRCUIT FOR GENERATING SUPPLY VOLTAGE FROM CHIP COMMUNICATION TERMINAL AND CHIP

(71) Applicant: HUIZHOU HAPPY VAPING TECHNOLOGY LIMITED, Huizhou (CN)

(72) Inventor: Xiyong Zhang, Shenzhen (CN)

(21) Appl. No.: 19/082,166

(22) Filed: Mar. 17, 2025

Related U.S. Application Data
(63) Continuation-in-part of application No. PCT/CN2024/071424, filed on Jan. 9, 2024.

(30) Foreign Application Priority Data
Mar. 7, 2023 (CN) 202320489589.0

(51) Int. Cl. H03K 5/24; G05F 1/625; H10D 89/10

(52) U.S. Cl. CPC H03K 5/24; G05F 1/625; H10D 89/10

(57) ABSTRACT

Provided are a circuit for generating a supply voltage from a chip communication terminal and a chip. The circuit includes electronic components provided in a chip and an energy storage capacitor (CAP) provided in the chip or externally attached to the chip. The electronic components include a diode, first P-channel metal-oxide-semiconductor (PMOS) transistor, and voltage comparator; an anode of the diode, a drain of the first PMOS transistor, and a negative input terminal of the voltage comparator are connected to a chip communication terminal; a cathode of the diode, a source and substrate of the first PMOS transistor, and a positive input terminal of the voltage comparator are connected to a chip power terminal; a gate of the first PMOS transistor is connected to an output terminal of the voltage comparator; and the CAP includes one terminal connected to the chip power terminal, and the other terminal grounded.

### CROSS REFERENCE TO RELATED APPLICATIONS

The present application is a Continuation-In-Part Application of PCT Application No. PCT/CN2024/071424 filed on Jan. 9, 2024, which claims the benefit of Chinese Patent Application No. 202320489589.0 filed on Mar. 7, 2023. All the above are hereby incorporated by reference in their entirety.

### TECHNICAL FIELD

The present disclosure relates to the technical field of integrated circuit (IC) design, and in particular to a circuit for generating a supply voltage from a chip communication terminal and a chip.

### BACKGROUND

For the conventional chip, the power supply is typically connected with a dedicated pin, so as to supply power to the internal circuit of the chip. However, the power pin and the supply circuit connected to it occupy a large area of the chip, resulting in a high cost of the chip.

### SUMMARY

### Technical Problems

An objective of the present disclosure is to provide a circuit for generating a supply voltage from a chip communication terminal and a chip, to overcome shortages of the above technology.

### Technical Solutions

To achieve the above objective of the present disclosure, the present disclosure provides the following technical solutions: A circuit for generating a supply voltage from a chip communication terminal includes a plurality of electronic components internally provided in the chip and an energy storage capacitor CAP internally provided in the chip or externally attached to the chip, where the electronic components include a diode D1, a first P-channel metal-oxide-semiconductor (PMOS) transistor M1, and a voltage comparator C1; an anode of the diode D1, a drain of the first PMOS transistor M1, and a negative input terminal of the voltage comparator C1 are connected to a chip communication terminal DATA; a cathode of the diode D1, a source and a substrate of the first PMOS transistor M1, and a positive input terminal of the voltage comparator C1 are connected to a chip power terminal VCC; a gate of the first PMOS transistor M1 is connected to an output terminal of the voltage comparator C1; and the energy storage capacitor CAP includes one terminal connected to the chip power terminal VCC, and the other terminal grounded.

Preferably, the electronic components each are provided with a power input port; and the power input port is connected to the chip power terminal VCC and powered by the chip power terminal VCC.

Preferably, the electronic components further include a second PMOS transistor M2 and a two-input OR gate A1; a drain of the second PMOS transistor M2 is connected to the chip communication terminal DATA; a source and a substrate of the second PMOS transistor M2 are connected to the chip power terminal VCC; and the two-input OR gate A1 includes one input terminal connected to the output terminal of the voltage comparator C1, the other input terminal being an enable signal terminal OD, and an output terminal connected to a gate of the second PMOS transistor M2.

Preferably, a channel width-to-length ratio WM2/LM2 of the second PMOS transistor M2 is greater than a channel width-to-length ratio WM1/LM1 of the first PMOS transistor M1; and a gate capacitance CG_M2 of the second PMOS transistor M2 is greater than a gate capacitance CG_M1 of the first PMOS transistor M1.

Preferably, a first body diode D2 is provided between the source and the substrate of the first PMOS transistor M1; and a second body diode D3 is provided between the source and the substrate of the second PMOS transistor M2.

In order to solve the same technical problem, an embodiment of the present disclosure further provides a chip, including the circuit for generating a supply voltage from a chip communication terminal.

### Beneficial Effects

According to the circuit for generating a supply voltage from a chip communication terminal provided by the present disclosure, with the voltage comparator C1 for detecting changes of voltages at the chip communication terminal DATA and the chip power terminal VCC, the chip power terminal VCC can track a high level of the chip communication terminal DATA. In response to a low level of the chip communication terminal DATA, a path between the chip power terminal VCC and the chip communication terminal DATA is cut off, and the energy storage capacitor CAP supplies the power, such that the chip power terminal VCC can supply the power to the chip continuously. Besides, the enhancement-mode PMOS transistor M2 is turned on at the same time to provide a high current, thereby ensuring that the chip power terminal VCC can achieve a powerful drive capability. With the internal supply circuit, the present disclosure omits the chip port of the power pin and the supply circuit thereof, thereby greatly saving the area and cost of the chip.

### BRIEF DESCRIPTION OF THE DRAWINGS

FIG. 1 is a schematic structural view of a circuit according to Embodiment 1 of the present disclosure;

FIG. 2 is a schematic structural view of a circuit according to Embodiment 2 of the present disclosure;

FIG. 3 is a schematic view of a chip including an internal energy storage capacitor and a circuit for generating a supply voltage from a chip communication terminal in single-bus communication according to Embodiment 2 of the present disclosure; and

FIG. 4 is a schematic view of a chip including an external energy storage capacitor and a circuit for generating a supply voltage from a chip communication terminal in single-bus communication according to Embodiment 2 of the present disclosure.

### DETAILED DESCRIPTION

### Preferred Implementations of the Present Disclosure

The present disclosure provides a circuit for generating a supply voltage from a chip communication terminal. The circuit is applied to provide the supply voltage for the chip. The chip includes a chip communication terminal DATA and a chip power terminal VCC. The chip power terminal VCC is internally provided, such that a power pin is omitted.

### Implementations of the Present Disclosure

The present disclosure will be described in detail below in conjunction with specific embodiments.

### Embodiment 1

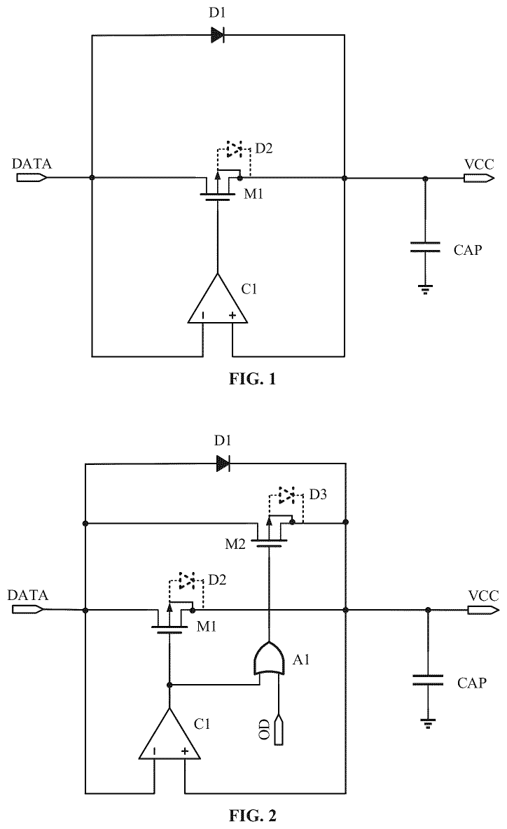

As shown in FIG. 1, the embodiment of the present disclosure provides a circuit for generating a supply voltage from a chip communication terminal. The circuit is provided with electronic components. The electronic components include a diode D1, a first PMOS transistor M1 and a voltage comparator C1 that are internally provided in the chip, and an energy storage capacitor CAP internally provided in the chip. An anode of the diode D1, a drain of the first PMOS transistor M1, and a negative input terminal of the voltage comparator C1 are connected to a chip communication terminal DATA. A cathode of the diode D1, a source and a substrate of the first PMOS transistor M1, and a positive input terminal of the voltage comparator C1 are connected to a chip power terminal VCC. A gate of the first PMOS transistor M1 is connected to an output terminal of the voltage comparator C1. The electronic components each are provided with a power input port. The power input port is connected to the chip power terminal VCC and powered by the chip power terminal VCC. The energy storage capacitor CAP includes one terminal connected to the chip power terminal VCC, and the other terminal grounded.

In other embodiments, the energy storage capacitor CAP may also be externally attached to the chip for use, so as to further reduce the area and cost of the chip.

As shown in FIG. 1, the working principle in the embodiment is as follows: In response to a sleep state of the chip, both the chip communication terminal DATA and the chip power terminal VCC have a low level. When a high level is input to the chip communication terminal DATA, the voltage comparator C1 outputs a logic signal “0”. Driven by the logic signal “0”, the first PMOS transistor M1 is turned on. The chip power terminal VCC quickly obtains a high level same as the high level of the chip communication terminal DATA, and can supply a power to the chip. Meanwhile, the energy storage capacitor CAP is charged to a high level same as the high level of the chip communication terminal DATA.

When the chip communication terminal DATA has a low level or a level less than a level of the chip power terminal VCC, the voltage comparator C1 outputs a logic signal “1”. Driven by the logic signal “1”, the first PMOS transistor M1 is turned off quickly. By this time, a voltage of the chip power terminal VCC is supplied by the energy storage capacitor CAP.

When the level of the chip power terminal VCC is less than a minimum level required by the circuit in work, and the level of the chip communication terminal DATA is greater than a threshold voltage Vth of the diode D1, the diode D1, the first PMOS transistor M1, and a first body diode D2 of the first PMOS transistor M1 supply an initial working voltage to start the circuit. When the level of the chip power terminal VCC is less than the level of the chip communication terminal DATA by the threshold voltage Vth, a higher drive current is supplied, such that the level of the chip power terminal VCC quickly tracks the level of the chip communication terminal DATA.

According to the circuit for generating a supply voltage from a chip communication terminal provided by the present disclosure, with the voltage comparator C1 for detecting changes of voltages at the chip communication terminal DATA and the chip power terminal VCC, the chip power terminal VCC can track the high level of the chip communication terminal DATA. In response to the low level of the chip communication terminal DATA, the path between the chip power terminal VCC and the chip communication terminal DATA is cut off, and the energy storage capacitor CAP supplies the power, such that the chip power terminal VCC can supply the power to the chip continuously.

### Embodiment 2

As shown in FIG. 2, the embodiment of the present disclosure provides a circuit for generating a supply voltage from a chip communication terminal. The circuit is provided with a plurality of electronic components internally provided in the chip and an energy storage capacitor CAP. The energy storage capacitor CAP is internally provided in the chip. The electronic components include a diode D1, a first PMOS transistor M1, a second PMOS transistor M2, a two-input OR gate A1, and a voltage comparator C1. An anode of the diode D1, a drain of the first PMOS transistor M1, a drain of the second PMOS transistor M2, and a negative input terminal of the voltage comparator C1 are connected to a chip communication terminal DATA. A cathode of the diode D1, a source and a substrate of the first PMOS transistor M1, a source and a substrate of the second PMOS transistor M2, and a positive input terminal of the voltage comparator C1 are connected to a chip power terminal VCC. A gate of the first PMOS transistor M1 is connected to an output terminal of the voltage comparator C1. The two-input OR gate A1 includes one input terminal connected to the output terminal of the voltage comparator C1, and the other input terminal being an enable signal terminal OD. A gate of the second PMOS transistor M2 is connected to an output terminal of the two-input OR gate A1. The electronic components each are provided with a power input port. The power input port is connected to the chip power terminal VCC and powered by the chip power terminal VCC. The energy storage capacitor CAP includes one terminal connected to the chip power terminal VCC, and the other terminal grounded.

Exemplarily, the signal of the enable signal terminal OD comes from the chip. Exemplarily, when a high-frequency clock, a high-power low dropout regulator (LDO), high-power memory operations of write, erase, read and the like are started in the chip, an open drain (OD) enable signal is generated by the chip, and input to the enable signal terminal OD.

The second PMOS transistor M2 is an enhancement-mode PMOS driver transistor. A channel width-to-length ratio WM2/LM2 of the second PMOS transistor M2 is greater than a channel width-to-length ratio WM1/LM1 of the first PMOS transistor M1. A gate capacitance CG_M2 of the second PMOS transistor M2 is greater than a gate capacitance CG_M1 of the first PMOS transistor M1.

In the embodiment, since the channel width-to-length ratio WM2/LM2 is greater than the channel width-to-length ratio WM1/LM1, an on-resistance of the second PMOS transistor M2 is less than an on-resistance of the first PMOS transistor M1, and thus the second PMOS transistor M2 obtains a higher on-state current to meet the functional requirement of the chip on high power consumption. Accordingly, the second PMOS transistor M2 generates a larger gate capacitance CG_M2 alternatively. If a control circuit of the first PMOS transistor M1 is used directly, it will take longer to turn off the second PMOS transistor M2. Hence, the first PMOS transistor M1 and the second PMOS transistor M2 are controlled respectively.

According to the circuit for generating a supply voltage from a chip communication terminal provided by the embodiment, a second body diode D3 is provided between the source and the substrate of the second PMOS transistor M2. A first body diode D2 is provided between the source and the substrate of the first PMOS transistor M1.

The first body diode D2 and the second body diode D3 are parasitic between the substrate and the source. In the present disclosure, a voltage of the chip power terminal VCC should be greater than or equal to a voltage of the chip communication terminal DATA. If the voltage of the chip power terminal VCC is less than the voltage of the chip communication terminal DATA, the chip communication terminal DATA automatically charges the chip power terminal VCC. This can ensure that the substrate of the first PMOS transistor M1 and the substrate of the second PMOS transistor M2 are connected to a high level.

In other embodiments, the energy storage capacitor CAP may also be externally attached to the chip for use, so as to further reduce the area and cost of the chip.

As shown in FIG. 2, the working principle in the embodiment is as follows: In response to a sleep state of the chip, both the chip communication terminal DATA and the chip power terminal VCC have a low level. When a high level is input to the chip communication terminal DATA, the voltage comparator C1 outputs a logic signal “0”. Driven by the logic signal “0”, the first PMOS transistor M1 is turned on. The chip power terminal VCC quickly obtains a high level same as the high level of the chip communication terminal DATA, and can supply a power to the chip. Meanwhile, the energy storage capacitor CAP is charged to a high level same as the high level of the chip communication terminal DATA.

When the chip communication terminal DATA has a low level or a level less than a level of the chip power terminal VCC, the voltage comparator C1 outputs a logic signal “1”. Driven by the logic signal “1”, the first PMOS transistor M1 is turned off quickly. By this time, a voltage of the chip power terminal VCC is supplied by the energy storage capacitor CAP.

When the level of the chip power terminal VCC is less than a minimum level required by the circuit in work, and the level of the chip communication terminal DATA is greater than a threshold voltage Vth of the diode D1, the diode D1, the first PMOS transistor M1, and a first body diode D2 of the first PMOS transistor M1 supply an initial working voltage to start the circuit. When the level of the chip power terminal VCC is less than the level of the chip communication terminal DATA by the threshold voltage Vth, a higher drive current is supplied, such that the level of the chip power terminal VCC quickly tracks the level of the chip communication terminal DATA.

When the high level is input to the chip communication terminal DATA, if an enable signal “0” is sent to the enable signal terminal OD, the two-input OR gate A1 outputs a logic signal “0”. Driven by the logic signal, the enhancement-mode PMOS transistor M2 is turned on, such that the chip power terminal VCC has a higher current. With the voltage comparator C1 for driving the second PMOS transistor M2 and the first PMOS transistor M1, lossless transmission from the level of the chip communication terminal DATA to the level of the chip power terminal VCC is realized.

When the enable signal of the enable signal terminal OD is deactivated, namely the enable signal is “1”, the second PMOS transistor M2 can be turned off, and the voltage comparator C1 directly drives the first PMOS transistor M1. When the level of the chip communication terminal DATA is less than the level of the chip power terminal VCC, the first PMOS transistor M1 can be turned off quickly to realize quick response, thereby preventing reverse current.

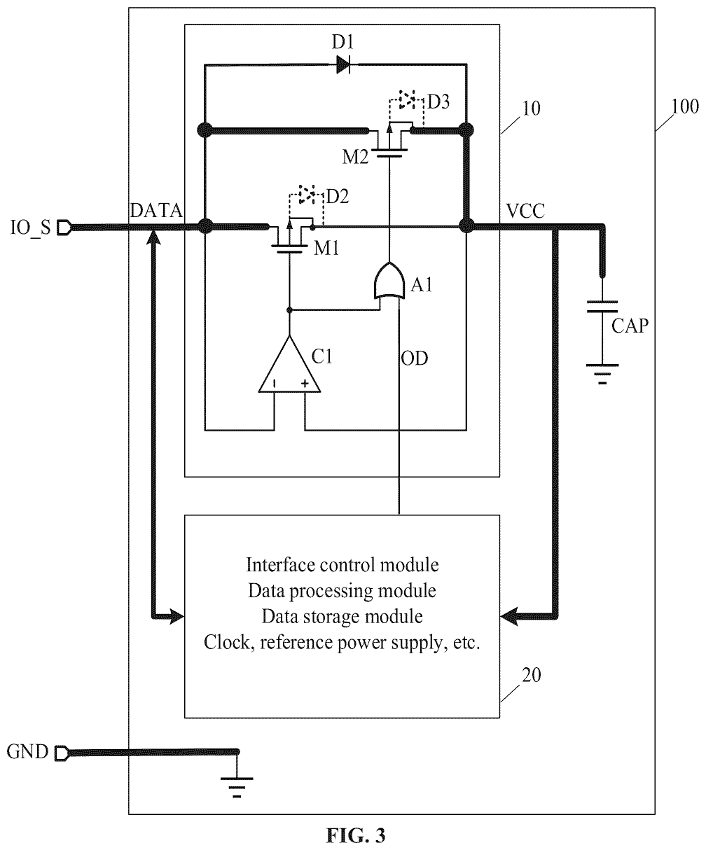

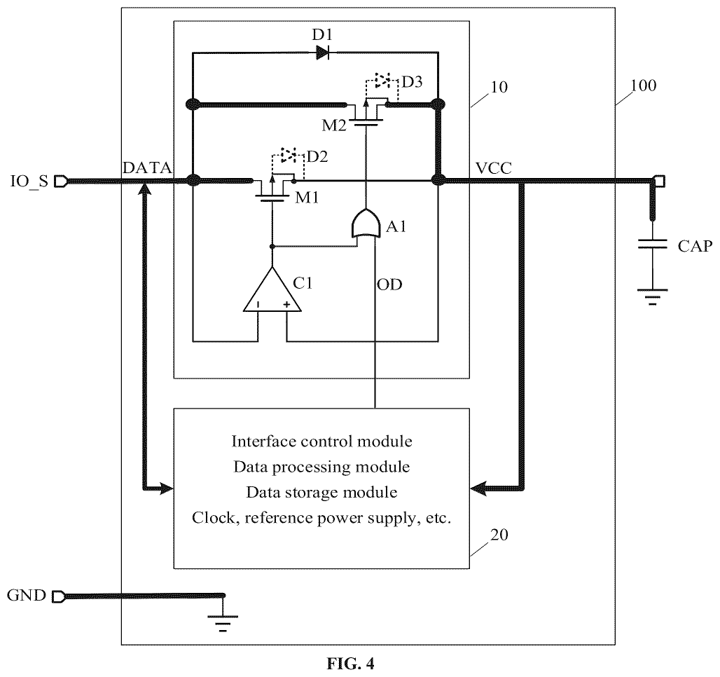

Referring to FIG. 3 and FIG. 4, the embodiment further provides a chip 100. The chip 100 includes the circuit 10 for generating a supply voltage from a chip communication terminal. In an optional implementation, the energy storage capacitor CAP is internally provided in the chip 100, as shown in FIG. 3.

In specific application, the chip 100 may also include other structures based on an actual use requirement. Exemplarily, referring to FIG. 3, the chip 100 further includes basic components 20 such as an interface control module, a data processing module, a data storage module, a clock, and a reference power supply.

In the embodiment of the present disclosure, the interface control module is configured for data communication. Exemplarily, the interface control module is configured to output the enable signal to the enable signal terminal OD. The data processing module is configured to process data. The data storage module is configured to store data. The clock is configured to provide a stable time reference for the chip 100. The reference power supply is configured to provide a stable voltage reference for each component in the chip 100.

In the embodiments of the present disclosure, the interface control module, the data processing module, and the data storage module each may be one or more processors, or controllers that each have a communication interface and can realize a communication protocol, and may further include a memory, a related interface and system transmission bus, and the like if necessary. The processor or the controller executes a program-related code to realize a corresponding function. In an alternative solution, the interface control module, the data processing module, and the data storage module share devices such as a processor, a controller and a memory. The shared processor or controller executes a program-related code to realize a corresponding function.

Referring to FIG. 3, in specific implementation, a communication terminal IO_S of the chip serves as the communication terminal of a final integrated chip, and labeled as the chip communication terminal DATA in the chip 100. The supply voltage is generated only by determining the level of the chip communication terminal DATA. However, for the modules such as the interface control module, the timing characteristic of the high level or the low level of the chip communication terminal DATA is further decoded into binary data, or the data of the chip is converted into the high level or the low level of the chip communication terminal DATA containing information.

Referring to FIG. 4, in another optional implementation, the energy storage capacitor CAP is connected to an outer surface of the chip 100.

In conclusion, according to the circuit for generating a supply voltage from a chip communication terminal provided by the present disclosure, with the voltage comparator C1 for detecting changes of voltages at the chip communication terminal DATA and the chip power terminal VCC, the chip power terminal VCC can track the high level of the chip communication terminal DATA. In response to the low level of the chip communication terminal DATA, the path between the chip power terminal VCC and the chip communication terminal DATA is cut off, and the energy storage capacitor CAP supplies the power, such that the chip power terminal VCC can supply the power to the chip continuously. Besides, the enhancement-mode PMOS transistor M2 is turned on at the same time to provide a high current, thereby ensuring that the chip power terminal VCC can achieve a powerful drive capability. In addition, the present disclosure omits the chip port of the power pin and the supply circuit thereof, thereby greatly saving the area and cost of the chip.

### INDUSTRIAL APPLICABILITY

The above are merely preferred embodiments of the present disclosure, and all equivalent changes and modifications made according to the scope of the claims of the present disclosure shall fall within the scope covered by the claims of the present disclosure.

1. A circuit for generating a supply voltage from a chip communication terminal, comprising a plurality of electronic components internally provided in a chip and an energy storage capacitor (CAP) internally provided in the chip or externally attached to the chip, wherein the electronic components comprise a diode (D1), a first P-channel metal-oxide-semiconductor (PMOS) transistor (M1), and a voltage comparator (C1); an anode of the diode (D1), a drain of the first PMOS transistor (M1), and a negative input terminal of the voltage comparator (C1) are connected to a chip communication terminal (DATA); a cathode of the diode (D1), a source and a substrate of the first PMOS transistor (M1), and a positive input terminal of the voltage comparator (C1) are connected to a chip power terminal (VCC); a gate of the first PMOS transistor (M1) is connected to an output terminal of the voltage comparator (C1); and the energy storage capacitor (CAP) comprises one terminal connected to the chip power terminal (VCC), and the other terminal grounded.

2. The circuit for generating a supply voltage from a chip communication terminal according to claim 1, wherein the electronic components each are provided with a power input port; and the power input port is connected to the chip power terminal (VCC) and powered by the chip power terminal (VCC).

3. The circuit for generating a supply voltage from a chip communication terminal according to claim 1, wherein the electronic components further comprise a second PMOS transistor (M2) and a two-input OR gate (A1); a drain of the second PMOS transistor (M2) is connected to the chip communication terminal (DATA); a source and a substrate of the second PMOS transistor (M2) are connected to the chip power terminal (VCC); and the two-input OR gate (A1) comprises one input terminal connected to the output terminal of the voltage comparator (C1), the other input terminal being an enable signal terminal (OD), and an output terminal connected to a gate of the second PMOS transistor (M2).

4. The circuit for generating a supply voltage from a chip communication terminal according to claim 3, wherein a channel width-to-length ratio WM2/LM2 of the second PMOS transistor (M2) is greater than a channel width-to-length ratio WM1/LM1 of the first PMOS transistor (M1); and a gate capacitance (CG_M2) of the second PMOS transistor (M2) is greater than a gate capacitance (CG_M1) of the first PMOS transistor (M1).

5. The circuit for generating a supply voltage from a chip communication terminal according to claim 3, wherein a first body diode (D2) is provided between the source and the substrate of the first PMOS transistor (M1); and a second body diode (D3) is provided between the source and the substrate of the second PMOS transistor (M2).

6. A chip, comprising the circuit for generating a supply voltage from a chip communication terminal according to claim 1.

7. A chip, comprising the circuit for generating a supply voltage from a chip communication terminal according to claim 2.

8. A chip, comprising the circuit for generating a supply voltage from a chip communication terminal according to claim 3.

9. A chip, comprising the circuit for generating a supply voltage from a chip communication terminal according to claim 4.

10. A chip, comprising the circuit for generating a supply voltage from a chip communication terminal according to claim 5.
